(19) United States
(12) Patent Application Publication
(10) Pub. No.: US 2020/0347500 A1
(43) Pub. Date: Nov. 5, 2020

(54) DEVICE FOR CONVEYING A GAS INTO A CHEMICAL VAPOUR DEPOSITION REACTOR

(71) Applicant: KOBUS SAS, MONTBONNOT-SAINT-MARTIN (FR)

(72) Inventors: Patrice Nal, Grenoble (FR); Christophe Borean, Le Touvet (FR)

(73) Assignee: KOBUS SAS, MONTBONNOT-SAINT-MARTIN (FR)

(21) Appl. No.: 16/295,256

(22) PCT Filed: Sep. 29, 2017
(86) PCT No.: PCT/EP2017/074799

§ 371 Date: Mar. 7, 2019

(30) Foreign Application Priority Data
Oct. 4, 2016 (FR) 1659559

(51) Int. Cl. C23C 16/509; H01J 37/32

(52) U.S. Cl. CPC C23C 16/509; H01J 37/32082; C23C 16/45565; H01J 37/32477; H01J 2237/3321; H01J 37/3244

(57) ABSTRACT

The present invention concerns a gas circulation device (1) for conveying a gas into a chemical vapour deposition reactor, comprising a conduit (2) with a first end (4) intended to open into said reactor, being polarised at a radiofrequency potential (V) and a second end (3) electrically polarised at a reference potential (V₀), the device being characterised in that it further comprises a means (10a-10e) for applying potential for locally applying at least one determined electrical potential to the conduit (2) between the first and the second end, so as to locally polarise the gas in said conduit at an intermediate electrical potential between the radiofrequency potential and the reference potential.

### FIELD OF THE INVENTION

The present invention relates to a device for conveying a gas into a chemical vapour deposition reactor for electrically conditioning the gas flowing in a conduit. The invention more particularly relates to such a device making it possible to prevent the gas flowing in such a conduit from being locally subjected to an excessive electric field due to an electrical potential imposed at the outlet of said conduit opening into the reactor.

### STATE OF THE ART

Chemical vapour deposition is commonly referred to by its Anglo-Saxon name “chemical vapour deposition” (CVD). In particular, this method can be used to deposit a thin film on the surface of a substrate from reaction gases through chemical reactions, particularly for semiconductor manufacturing. In this case, the reaction gases comprise a precursor gas injected into the reactor deposition chamber, for example, by a first injection path and a reactant gas injected into the reactor deposition chamber, for example, by a second injection path separate from the first one, so that it only mixes once it has entered said deposition chamber.

Among the existing variants of the CVD method, the plasma enhanced chemical vapour deposition (PECVD) method is of particular interest. It comprises the formation of a plasma from the reaction gases by supplying electrical energy from a radiofrequency source that generates a sufficiently high radiofrequency potential (RFV) difference between two electrodes or two portions of the device acting as electrodes. Plasma provides the energy necessary for the deposition of the thin film on the surface of the substrate while limiting the supply of thermal energy, by maintaining electrons at a high level of excitation. Thus, the PECVD method can be implemented at significantly lower temperatures than other variants of the CVD method, and enables good quality layer deposits to be achieved.

In practice, the outlet of the gas conduits that inject the reaction gases into the chamber is generally brought to the radiofrequency potential by the radiofrequency source. The substrate to be treated has a potential of zero, or at least corresponding to the ground potential of the electrical circuit. This difference in potential generates a plasma inside the chamber by causing the ionization of the reaction gases. The latter causes the precursor gas to dissociate, then the desired layer to form on the substrate by reactions of the precursor gas with the reactant gas, and thus the formation of a layer on the surface of the substrate.

However, the presence of a VRF potential at the gas conduit outlet has the disadvantage of possibly causing the partial ionization of the reaction gas, in particular the precursor gas and/or the reactant gas in their respective circulation conduits, even before they enter the reactor chamber. Indeed, the inlet of the conduit or at least the portions upstream of its outlet are also at zero potential, corresponding to the ground potential of the electrical circuit. This potential difference between the outlet of the conduit and an upstream portion of the conduit can cause a gas plasma to form in the gas circulation conduit, and degrade the quality of the deposit.

In order to solve this problem, it is known to use a resistive sleeve which can take the form of a sheath made of an electrically resistive material surrounding the gas circulation conduits. The total electrical resistance of the sleeve is chosen in such a way as to limit the energy supply in the gas and thus avoid the risk of breakdown and plasma formation.

For example, U.S. Pat. No. 6,170,430 describes the use of a resistive sheath around the gas conduits to form a linear gradient of electrical voltage along said gas conduits.

However, such resistive sheaths are not sufficient to prevent any risk of plasma formation in the conduits, particularly in PECVD processes in which the pressure in the conduits varies (e.g. due to pulse gas injections . . . ). Indeed, since the local impedance of the gas in the conduit depends on pressure, it may be possible to locally reach a breakdown voltage even by imposing a linear voltage gradient.

### SUMMARY OF THE INVENTION

The purpose of this invention is therefore to remedy the disadvantages of the prior art by proposing a gas circulation device enabling an electrical conditioning of a gas flowing in a conduit intended to prevent the formation of plasma in said gas circulation conduit.

An object of the invention is a gas circulation device for conveying a gas into a chemical vapour deposition reactor, comprising a conduit with a first end intended to open into said reactor while being polarised at a radiofrequency potential and a second end electrically polarised at a reference potential, the device being characterized in that it further comprises a potential applying means for locally applying at least one determined electrical potential to the conduit between the first and the second end, so as to locally polarise the gas in said conduit at an intermediate electrical potential between the radiofrequency potential and the reference potential.

In this text, “electrical conditioning” means the imposition of one or more determined electrical voltage(s) on the gas flowing in the conduit.

The device according to the invention also aims to prevent the formation of plasma in the gas circulation conduit in the presence of significant variations in gas injection pressure, for example during pulse injections of said gas.

According to one embodiment, the potential applying means includes at least one voltage source so arranged as to impose a potential on a portion of the conduit.

According to another embodiment, the potential applying means comprises a voltage divider electrically connected according to two terminals respectively to the potential of the first and the second end of the conduit, said voltage divider comprising a plurality of electrical impedance modules connected in series, at least one junction between two successive electrical impedance modules being electrically connected to the conduit.

The device advantageously comprises an electrical impedance module with at least one of the following components: a resistor, an inductor, a coil, a capacitor.

According to one embodiment, the conduit comprises at least one electrically conductive portion so arranged as to be in contact with the gas flowing in said conduit and surrounded by electrically insulating portions.

The conduit may comprise an electrically insulating portion of having the shape of a section of said conduit.

In addition, the conduit may comprise an electrically conductive portion having the shape of a section of said conduit.

According to one embodiment, the conduit has a substantially uniform inner section.

In particular, the conduit may include an electrically insulating portion having the shape of a tube section.

According to one embodiment, the conduit comprises at least one electrically conductive portion having the shape of a part made of an electrically conductive material with at least one gas circulation through chamber.

Said through chamber can define a non-rectilinear gas path in said electrically conductive portion.

According to one embodiment, the conduit comprises at least one electrically conductive portion having the shape of a part made of an electrically conductive material with a plurality of openings enabling gas circulation.

Another purpose of the invention is to propose a reactor for chemical gas deposition comprising one or more gas circulation device(s) with such an electrical conditioning device, making it possible to avoid the formation of plasma in the gas circulation conduit or conduits.

According to one embodiment, said reactor comprises two electrodes, a first electrode of which is connected to a radiofrequency source, and a second electrode is connected to the ground, so that the potential difference between the first and the second electrodes makes it possible to form a plasma of the gas(es) injected into the reactor.

A third object of the invention relates to a method for avoiding the formation of plasma in a gas injection conduit of a chemical vapour deposition reactor, such as the reactor described above, said reactor comprising a conduit with a first end opening into said reactor being polarised to a radiofrequency potential and a second end electrically polarised to a reference potential. Said method is characterized in that it comprises locally applying at least one determined electrical potential to the conduit between the first and the second ends, so as to locally polarise the gas in said conduit at an intermediate electrical potential between the radiofrequency potential and the reference potential.

A fourth subject of the invention relates to a method for chemical vapour deposition implemented by the reactor described above.

This method involves the injection of one or more gas(es) intended to react on the surface of a substrate previously positioned in the reactor reaction chamber via a gas circulation device as described above.

Thus, the invention makes it possible to impose predetermined electrical potentials on the gas according to the position in the conduit. It thus makes it possible to impose any potential profile along the conduit.

The potential profile can thus be linear, non-linear, quadratic, logarithmic, etc.

The potential profile can also be proportional, inversely proportional, or a function of a gas pressure profile depending on the position in the conduit.

The imposed potential profile is essentially linear in pieces. By applying a specific electrical potential to each electrically conductive part, a similarly determined potential difference is imposed on the gas between two successive conductive portions. This generates a local electric field that depends on the distance between the conductive portions and the potential difference.

The profile of the local potential or electric field can be modulated, for example:
By arranging the successive conductive portions in a non-equidistant manner, or in other words by interposing insulating portions of variable or different length between the conductive portions; and/or
By applying potentials to conductive portions generating different potential differences for different insulating portions. For this purpose, for example, a voltage divider can be used with successive electrical impedance modules of different values.

Of course, the invention can also be implemented with:
Insulating portions having an identical length on all or part of the conduit; and/or
Successive electrical impedance modules of identical value over all or part of the conduit.

Preferably, the conductive portions are in direct contact with the gas, which ensures optimal flow of electrical charges and good homogeneity over a section of the conduit of the applied electrical potential.

### DESCRIPTION OF THE FIGURES

Other advantages and characteristics of the invention will appear when reading the following description given as an illustrative and non-exhaustive example, with reference to the annexed drawings on which:

FIG. 1, which represents a diagram of the structure of the electrical conditioning device of a gas circulation conduit according to a first object of the invention, the conduit opening into the plasma assisted chemical vapour deposition (PECVD) reactor according to a second object of the invention;

FIG. 2 schematically shows one embodiment of an electrically conductive portion of the conduit.

### DETAILED DESCRIPTION OF THE INVENTION

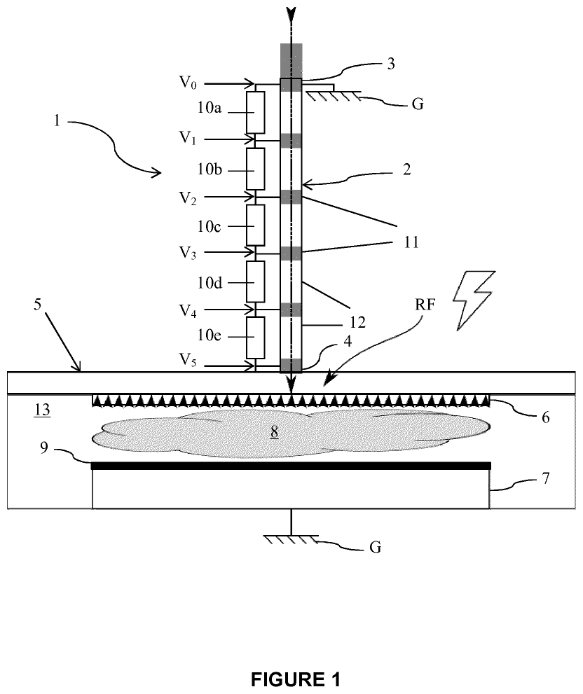

A first subject of the invention relates to a gas circulation device 1 for conveying a gas into a chemical vapour deposition reactor, the structure of which is shown in FIG. 1.

The device comprises a gas conduit 2 which is intended to bring the gas from a source (not shown) to the reactor chamber, in the direction of the arrow confused with the axis of symmetry of said conduit.

The inlet 3 of the gas conduit is located at a first end, and is connected to a reference electrical potential which, in the embodiment shown, corresponds to the ground G of the electrical circuit. Its electrical potential V₀ is therefore zero.

The outlet 4 of the conduit is located at a second end, and is connected to a radio frequency source RF that imposes an electrical potential V₅=V_{RF} at a high frequency (typically 13.56 MHz).

Thus, the gas conduit 2 is subjected to a potential difference between its terminals 3 and 4, equal to V₅−V₀.

The electrical conditioning of the gas flowing in the conduit consists in locally imposing at least one electrical potential determined on said gas, said potential being intermediate between the radiofrequency potential V₅ and the reference potential V₀.

Thus, the gas flowing in the conduit is subjected, between two zones where the potential is imposed, to a potential difference lower than the potential difference V₅−V₀, sufficiently low to minimize the risks of plasma generation within the conduit.

The potential difference V₅−V₀ can advantageously be divided into as many potential differences as necessary, located along the conduit. This makes it possible to better monitor or control the local values of the electric field in the conduit, and to ensure that this electric field never reaches, even locally, an intensity sufficient to generate a plasma.

For this purpose, the conduit shall comprise at least one electrically conductive portion arranged to be in contact with the gas flowing in said conduit and surrounded by electrically insulating portions. In the embodiment of FIG. 1, the electrically conductive portions are greyed out and designated by the mark 11, while the electrically insulating portions are white and designated by the mark 12.

Preferably, each electrically conductive portion has the shape of a part made of an electrically conductive material defining internally at least one gas circulation through channel. Externally, said electrically conductive portion includes any means adapted for applying an electrical potential. The person skilled in the art is able to design any appropriate electrical connector for this purpose.

The greater the contact surface between the gas and the electrically conductive portion, the more effective the application of said potential to the gas. Therefore, it is preferable to ensure that the electrically conductive portion extends over a certain length of the gas flow by completely surrounding said gas flow.

Thus, advantageously, said electrically conductive portion forms a section of the conduit.

On either side of this electrically conductive portion there are electrically insulating portions, each of which preferably forms a section of the conduit.

Each electrically insulating portion advantageously has the shape of a tube section, as in a conventional conduit.

Preferably, the conduit has a substantially uniform inner section. In particular, the circulation device is designed to avoid variations in the section of the gas passage between an electrically conductive portion and an electrically insulating portion. This makes it possible to limit the turbulence of the gas flow in the conduit, and therefore the risk of residue deposits on the walls.

The device 1 comprises means for locally applying at least one determined electrical potential to the conduit between its first high end 3 and its second low end 4 at each electrically conductive portion. The potential applying means allows several potentials to be applied along the conduit, referenced V₁, V₂, V₃, V₄ in FIG. 1.

The difference between two successive potentials V₀, V₁, V₂, V₃, V₄, and V₅ represents a fraction of the potential difference V_{RF} which the conduit 2 is subjected to. Thus, the sum of these potential differences is equal to the potential difference V_{RF} of the gas conduit 2.

Preferably, the value of a potential is greater than or equal to that of the potential preceding it, and less than or equal to that of the potential following it, considering the gas circulation direction in the conduit, from its first end 3 to its second end 4. In this case, the following inequality is verified:

V₀=0≤V₁≤V₂≤V₃≤V₄≤V₅=V_{RF}.

Therefore, a first conduit portion (in the upstream direction) is subjected to a potential difference equal to V₁−V₀, and the successive adjacent conduit portions are subjected to a potential difference equal to V₂−V₁, V₃−V₂, V₄−V₃, and V₅−V₄ respectively.

Thus, by dividing the potential difference of the gas conduit 2 into at least two fractions, by applying at least one specific potential located at the gas flowing in said conduit, “potential steps” are formed.

According to a first embodiment of the invention (not illustrated), the potential applying means comprises at least one source of electrical voltage to apply the electrical potential values along the gas conduit.

According to a second embodiment of the invention, the potential applying means comprises a plurality of impedance modules distributed along the gas conduit, between two successive electrically conductive portions, and connected in series.

“Impedance module” refers to any electrical or electronic component that has the property of preventing the passage of an electrical current.

Thus, according to the second embodiment of the invention, an impedance module may include, for example, a resistance, an inductor, a coil, or a capacitor, or a combination of these components.

In the embodiment shown in FIG. 1, the voltage source includes five resistors, referenced 10a, 10b, 10c, 10d, and 10e, connected in series between the first end 3 and the second end 4 of the gas conduit 2. Each junction between two successive impedances is electrically connected to an electrically conductive portion 11 of the conduit in contact with the gas.

It should be noted that the representation of the conduit 2 as a tube in FIG. 1 is purely schematic. It goes without saying that the internal and/or external geometry of the conduit can be adapted to allow the application of the above-mentioned intermediate potential(s) and/or to connect different portions of the conduit with each other. The person skilled in the art will be able to define these adaptations.

Moreover, although the conduit 2 is shown straight in FIG. 1, it goes without saying that the person skilled in the art will be able to vary the geometry of the conduit without going beyond the scope of this invention.

In particular, the invention may include at least one electrically conductive portion 11 with a so-called “non-rectilinear” through chamber in the sense that it is so arranged as to define a non-rectilinear gas path.

Such a non-rectilinear through chamber allows on the one hand to increase the gas surface in contact with the imposed potential, and on the other hand to create turbulence in the gas flow to increase the amount of gas in contact with the imposed potential, without affecting the length of the device.

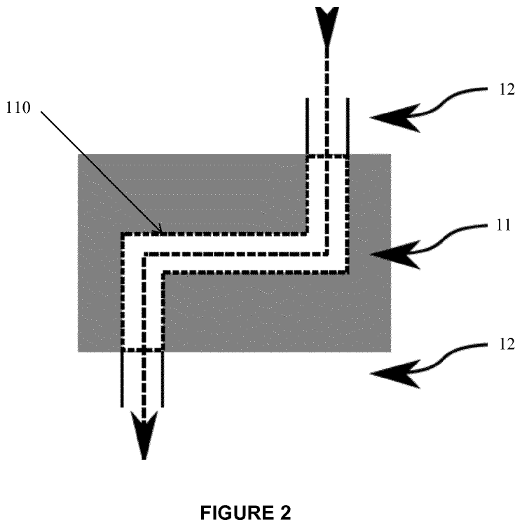

According to embodiments, this through chamber can include in particular:
a gas inlet and a gas outlet (at least) offset with respect to the direction of the gas flow, i. e. not opposite same;
a cavity having a cylindrical cross-section (or any other type of cross-section) with a gas inlet and a gas outlet (at least) offset with respect to the direction of the gas flow. According to another embodiment illustrated in FIG. 2, an electrically conductive portion 11 comprises a through chamber in the form of a non-rectilinear 110 through channel, comprising, for example, one more or less pronounced bend(s), and connecting a gas inlet and a gas outlet offset with respect to the direction of the gas flow. Naturally, the geometries mentioned and in particular the geometry presented in FIG. 2 correspond only to a particular embodiment, the person skilled in the art being able to adjust the gas path according to the injection conditions and the risks of plasma generation.

According to other embodiments, the invention may include at least one cutout or latticed electrically conductive portion 11, or may include a plurality of openings allowing the passage of gas through said electrically conductive portion 11. These openings can be longitudinal in the sense that they are oriented in the same direction as the gas flow. Such a provision also makes it possible to increase the quantity of gas in contact with the imposed potential, without affecting the length of the device.

Moreover, the different electrically conductive portions 11 do not necessarily have the same geometry. Similarly, the different electrically insulating portions 12 do not necessarily have the same geometry or length.

A second subject of the invention relates to a reactor 5 for implementing a plasma-assisted chemical vapour deposition (PECVD) method, comprising one or more device(s) 1 described above.

The reactor 5 is advantageously equipped with a showerhead 6 for distributing the gases opening into the reactor chamber 13. This shower 6 preferably comprises two gas injection channels. It receives the gases from one or more gas line(s) 2 and injects same into the reactor chamber. In doing so, the gases distributed by the shower have a potential equal to RF when they enter the reactor chamber. The distribution shower is preferably adapted to homogeneously distribute the gases on the surface of a substrate 9 previously placed on a substrate holder 7 in the reaction chamber 13, on which a subsequent deposition must be carried out.

A distribution shower that can be used in this invention is described in document FR2930561.

Advantageously, the reactor has two parallel electrodes, a first electrode of which is connected to a radiofrequency source, and a second electrode is connected to the ground. The potential difference between the first and the second electrode enables to form a plasma of the gas(es) injected into the reactor 5 via a gas injection conduit.

Preferably, the first electrode comprises the gas distribution shower 6 with the injection channels. The second electrode comprises the substrate 9 and the substrate holder 7.

An advantage of a reactor comprising one or more gas circulation device(s) as described above is the possibility of forming an electric field profile adapted to the parameters of the plasma assisted gas deposition (PECVD) method implemented by this reactor.

The parameters of the PECVD method include, for example: the nature of the precursor gas and its injection pressure, the nature of the reactant gas and its injection pressure, the method operating temperature, the size of the reactor, the intensity of the electric field generated by the electrodes in the reactor chamber, or the radio frequency potential RF at the gas injection conduit outlet.

In addition, the invention makes it possible to efficiently implement plasma-assisted gas deposition (PECVD) processes in which the gases are injected into the reactor chamber impulsively, or in the form of pulses, in phase or out of phase over time. In this case, the gas density in the conduits is highly variable over time, depending on whether or not a gas pulse is being injected into the reactor chamber. The result is that the electrical impedance of the medium in the conduit can also be highly spatially and/or temporally variable and locally allow the appearance of electric fields strong enough to trigger the ignition of a plasma. In this case, the invention, by locally controlling the differences in potential present at any point in the conduit, makes it possible to avoid the appearance of such excessive electric fields.

### REFERENCES

U.S. Pat. No. 6,170,430
FR 2930561

1. A gas circulation device for conveying a gas into a chemical vapour deposition reactor, comprising a conduit with a first end intended to open into said reactor while being polarised at a radiofrequency potential and a second end electrically polarised at a reference potential, the device further comprising a potential applying means for locally applying at least one determined electrical potential to the conduit between the first and the second end, so as to locally polarise the gas in said conduit at an intermediate electrical potential between the radio frequency potential and the reference potential.

2. The device according to claim 1, wherein the potential applying means further comprising at least one voltage source so arranged as to impose a potential on a portion of the conduit.

3. The device according to claim 1, wherein the potential applying means further comprising a voltage divider electrically connected according to two terminals respectively to the potential of the first and the second end of the conduit, said voltage divider comprising a plurality of electrical impedance modules connected in series, at least one junction between two successive electrical impedance modules being electrically connected to the conduit.

4. The device according to claim 3, further comprising an electrical impedance module with at least one of the following components: a resistor, an inductor, a coil, a capacitor.

5. The device according to claim 1, wherein the conduit further comprising at least one electrically conductive portion so arranged as to be in contact with the gas flowing in said conduit and surrounded by electrically insulating portions.

6. The device according to claim 5, wherein the conduit further comprising an electrically insulating portion having the shape of a section of said conduit.

7. The device according to claim 5, wherein the conduit further comprising an electrically conductive portion having the shape of a section of said conduit.

8. The device according to claim 1, wherein the conduit has a substantially uniform inner section.

9. The device according to claim 5, wherein the conduit further comprising an electrically insulating portion having the shape of a tube section.

10. The device according to claim 5, wherein the conduit further comprising at least one electrically conductive portion having the shape of a part made of an electrically conductive material with at least one through chamber for gas circulation.

11. The device according to claim 10, wherein said through chamber defines a non-rectilinear gas path in said electrically conductive portion.

12. The device according to claim 5, wherein the conduit further comprising at least one electrically conductive portion having the shape of a part made of an electrically conductive material with a plurality of openings enabling gas circulation.

13. A reactor for implementing a chemical vapour deposition method, the method comprising a reaction chamber and at least one gas circulation device according to claim 1.

14. The reactor according to claim 13, further comprising two electrodes, a first electrode of which is connected to a radiofrequency source, and a second electrode is connected to the ground, so that the potential difference between the first and the second electrodes enables to form a plasma of the gas(es) injected into the reactor.

15. A method for preventing plasma formation in a gas circulation device for conveying a gas to a chemical vapour deposition reactor, comprising a conduit with a first end opening into said reactor while being polarised at a radiofrequency potential and a second end electrically polarised at a reference potential, said method further comprising locally applying at least one determined electrical potential to the conduit between the first and the second end, so as to locally polarise the gas in said conduit at an intermediate electrical potential between the radiofrequency potential and the reference potential.

16. A method for chemical vapour deposition, implemented in a reactor according to claim 13, the method comprising a step of injecting, via a gas circulation device according to claim 1, a gas for reacting on the surface of a substrate previously positioned in the reactor reaction chamber.
